(19) United States
(12) Patent Application Publication
(10) Pub. No.: US 2024/0304372 A1
(43) Pub. Date: Sep. 12, 2024

(54) A CO-PLANAR TRANSFORMER AND WINDING CONFIGURATION

(71) Applicant: McMaster University, Hamilton (CA)

(72) Inventors: Mehdi Narimani, Oakville (CA); Omar Zayed, Hamilton (CA)

(21) Appl. No.: 18/600,226

(22) Filed: Mar. 8, 2024

Related U.S. Application Data
(60) Provisional application No. 63/451,444, filed on Mar. 10, 2023.

(51) Int. Cl. H01F 27/28; H02M 3/335; H05K 1/14

(52) U.S. Cl. CPC H01F 27/2804; H02M 3/335; H05K 1/14; H01F 2027/2809

(57) ABSTRACT

A co-planar transformer is provided. A dual-active bridge converter comprising the co-planar transformer is also provided. The co-planar transformer comprises a printed circuit board with a plurality of primary windings and a plurality of secondary windings. The number of primary winding turns is equal to the number of secondary winding turns. The plurality of primary windings and the plurality of secondary windings are provided on the same printed circuit board in an interleaving configuration, wherein the interleaving is provided horizontally across the printed circuit board. Other embodiments of co-planar transformers include two or more such printed circuit boards with interleaved plurality of primary and secondary windings.

### CROSS REFERENCE TO RELATED APPLICATION

The present disclosure claims priority from U.S. provisional application No. 63/451,444 filed on Mar. 10, 2023, which is hereby incorporated by reference in its entirety.

### FIELD

The described embodiments generally relate to systems and methods for an improved planar transformer design, and particularly for systems and methods for a co-planar transformer configuration with low parasitic capacitance.

### BACKGROUND

Switching frequency of power converters has been on a rising trend in medium to low power applications since it can lead to higher power density, which is key to higher levels of electrification especially in the transportation sector. And next generation device technologies such as silicon carbide (SiC) and gallium nitride (GaN) are of increasing popularity to keep up with the rising demand in the electrified market. Power magnetics are a central part of almost any power converter and contributes heavily to the overall size and footprint of the power converter.

To ensure the continued advancement of power converters and avoid bottlenecks, planar magnetics are proving to be an excellent alternative to conventional wire wound magnetics due to their flat-profile cores, low leakage, ease of manufacturing, controlled repeatability, and superior thermal performance especially at frequencies above 100 KHz.

However, there are many challenges accompanied with a conventional transformer structure, such as, for example, high inter/intra-winding parasitic capacitance, low inherent immunity to proximity effect and higher leakage flux. Accordingly, improved planar transformer configurations are desired.

### SUMMARY

The following summary is provided to introduce the reader to the more detailed discussion to follow. The summary is not intended to limit or define any claimed or as yet unclaimed invention. One or more inventions may reside in any combination or sub-combination of the elements or process steps disclosed in any part of this document including its claims and figures.

In a first aspect, in at least one embodiment, there is provided a co-planar transformer. The co-planar transformer comprises a printed circuit board comprising a plurality of primary windings and a plurality of secondary windings, where a number of the plurality of primary windings is equal to a number of the plurality of secondary windings, where the plurality of primary windings and the plurality of secondary windings are provided on the printed circuit board, and where the plurality of primary windings and the plurality of secondary windings are in an interleaving configuration, wherein the interleaving is provided horizontally across the printed circuit board.

In some cases, the printed circuit board is a two-layer board, and the interleaving configuration of the plurality of the primary windings and the plurality of the secondary windings is duplicated on the two layers of the printed circuit board, and each of the plurality of primary and secondary windings on a top layer of the two-layer board is connected in parallel to a corresponding winding on a bottom layer of the two-layer board through a corresponding via.

In some cases, the co-planar transformer comprises two printed circuit boards and the plurality of primary windings of each of a first and a second printed circuit board of the two printed circuit boards are connected in series.

In some cases, the plurality of secondary windings of each of the first and the second printed circuit boards are connected in parallel.

In some cases, the plurality of primary windings of each of the first and second printed circuit boards are connected through soldered copper rods.

In some cases, the plurality of secondary windings of each of the first and second printed circuit boards are connected through connection rods inserted through parallel pads for each secondary winding on each board.

In some cases, the co-planar transformer comprises three stacks of printed circuit boards, where each stack comprises six printed circuit boards connected in parallel to each other, and the three stacks are connected in series to each other.

In accordance with a further aspect, in at least one embodiment, there is provided a dual-active bridge converter. The dual-active bridge converter comprises a primary circuit coupled to an input voltage, a secondary circuit coupled to an output voltage and a co-planar transformer isolating the primary circuit from the secondary circuit. The co-planar transformer comprises a printed circuit board comprising a plurality of primary windings and a plurality of secondary windings, where a number of the plurality of primary windings is equal to a number of the plurality of secondary windings, where the plurality of primary windings and the plurality of secondary windings are provided on the printed circuit board, and where the plurality of primary windings and the plurality of secondary windings are in an interleaving configuration, wherein the interleaving is provided horizontally across the printed circuit board.

In some cases, the primary circuit comprises four input bridge switches, and the plurality of primary windings comprising a corresponding primary voltage and a primary current.

In some cases, the dual-active bridge converter further comprises an input capacitor in parallel to the four input bridge switches.

In some cases, the secondary circuit comprises four output bridge circuits, and the plurality of secondary windings comprising a corresponding secondary voltage and a secondary current.

In some cases, the dual-active bridge converter further comprises an output capacitor in parallel to the four output bridge switches.

### BRIEF DESCRIPTION OF THE DRAWINGS

The drawings included herewith are for illustrating various examples of articles, methods, and apparatuses of the present specification and are not intended to limit the scope of what is taught in any way. In the drawings:

FIG. 1A is a diagram showing a round conductor according to an example.

FIG. 1B is a diagram showing a planar conductor according to an example.

FIG. 1C is a diagram showing a surface area of a round conductor of FIG. 1A.

FIG. 1D is a diagram showing a surface area of a planar conductor of FIG. 1B.

FIG. 2 is a graph showing a plot of surface area ratio between planar and round conductors.

FIG. 3 is a schematic diagram showing an equivalent circuit model of a planar transformer according to an example.

FIG. 4 is a diagram of a fully interleaved planar transformer configuration according to an example.

FIG. 5A is a diagram showing a winding arrangement for a fully interleaved planar transformer according to an example.

FIG. 5B is a graph showing a plot of electrostatic energy with respect to distance for the fully interleaved planar transformer of FIG. 5A.

FIG. 6A is a diagram showing a winding arrangement for an alternating planar transformer according to an example.

FIG. 6B is a graph showing a plot of electrostatic energy with respect to distance for the alternating planar transformer of FIG. 6A.

FIG. 7A is a diagram showing a winding arrangement for a zero-voltage gradient planar transformer according to an example.

FIG. 7B is a graph showing a plot of electrostatic energy with respect to distance for the zero-voltage gradient planar transformer of FIG. 7A.

FIG. 8A is a diagram showing a top view of a co-planar transformer according to an example.

FIG. 8B is a diagram showing a bottom view of the co-planar transformer of FIG. 8A according to an example.

FIG. 8C is a diagram showing a winding arrangement for the co-planar transformer of FIG. 8A according to an example.

FIG. 8D is a diagram showing another representation of the winding arrangement of FIG. 8C.

FIG. 9 is a diagram showing a view of a co-planar transformer according to another example.

FIG. 10A is a diagram showing a view of a co-planar transformer according to a further example.

FIG. 10B is a diagram showing another representation of the co-planar transformer of FIG. 10A.

FIG. 11 is a schematic diagram showing an equivalent circuit model of a planar transformer according to another example.

FIG. 12A is a graph showing a plot of electrostatic energy density for the non-interleaved planar transformer.

FIG. 12B is a graph showing a plot of electrostatic energy density for the alternating fully interleaved planar transformer.

FIG. 12C is a graph showing a plot of electrostatic energy density for the zero-voltage gradient planar transformer.

FIG. 12D is a graph showing a plot of electrostatic energy density for the co-planar transformer.

FIG. 13A is a graph showing a plot of current density for the non-interleaved planar transformer.

FIG. 13B is a graph showing a plot of current density for the alternating fully interleaved planar transformer.

FIG. 13C is a graph showing a plot of current density for the zero-voltage gradient planar transformer.

FIG. 13D is a graph showing a plot of current density for the co-planar transformer.

FIG. 13E is a graph showing a plot of core and copper losses for various planar transformers.

FIG. 13F is a graph showing a plot of winding DC and AC resistance for various planar transformers.

FIG. 14 is a 3-dimensional (3D) schematic view of an experimental setup of various planar transformers according to an example.

FIG. 15A is a graph showing plots of stray capacitance measurements for various planar transformers according to an example.

FIG. 15B is a graph showing plots of inter-winding capacitance measurements for various planar transformers according to an example.

FIG. 16A is a graph showing plots of stray capacitance measurements for various planar transformers according to an example.

FIG. 16B is a graph showing plots of resonant frequencies for various planar transformers corresponding to FIG. 16A according to an example.

FIG. 16C is a graph showing plots of inter-winding capacitance measurements for various planar transformers according to an example.

FIG. 16D is a graph showing plots of resonant frequencies for various planar transformers corresponding to FIG. 16C according to an example.

FIG. 17 is a schematic diagram of a dual-active bridge converter according to an example.

FIG. 18A is a graph showing voltage and current plots for the traditional planar transformer.

FIG. 18B is a graph showing voltage and current plots for the alternating fully interleaved planar transformer.

FIG. 18C is a graph showing voltage and current plots for the zero-voltage gradient planar transformer.

FIG. 18D is a graph showing voltage and current plots for the co-planar transformer.

FIG. 18E is a graph showing voltage overshoot plots for various planar transformers.

FIG. 18F is a graph showing secondary RMS current plots for various planar transformers.

FIG. 19A is a graph showing voltage overshoot plots for various planar transformers.

FIG. 19B is a graph showing converter efficiency plots for various planar transformers.

FIG. 20 is a graph showing converter efficiency plots for various planar transformers.

### DETAILED DESCRIPTION

Numerous embodiments are described in this application and are presented for illustrative purposes only. The described embodiments are not intended to be limiting in any sense. The invention is widely applicable to numerous embodiments, as is readily apparent from the disclosure herein. Those skilled in the art will recognize that the present invention may be practiced with modification and alteration without departing from the teachings disclosed herein. Although particular features of the present invention may be described with reference to one or more particular embodiments or figures, it should be understood that such features are not limited to usage in the one or more particular embodiments or figures with reference to which they are described.

The terms “an embodiment,” “embodiment,” “embodiments,” “the embodiment,” “the embodiments,” “one or more embodiments,” “some embodiments,” and “one embodiment” mean “one or more (but not all) embodiments of the present invention(s),” unless expressly specified otherwise.

The terms “including,” “comprising” and variations thereof mean “including but not limited to,” unless expressly specified otherwise. A listing of items does not imply that any or all of the items are mutually exclusive, unless expressly specified otherwise. The terms “a,” “an” and “the” mean “one or more,” unless expressly specified otherwise.

As used herein and in the claims, two or more parts are said to be “coupled”, “connected”, “attached”, “joined”, “affixed”, or “fastened” where the parts are joined or operate together either directly or indirectly (i.e., through one or more intermediate parts), so long as a link occurs. As used herein and in the claims, two or more parts are said to be “directly coupled”, “directly connected”, “directly attached”, “directly joined”, “directly affixed”, or “directly fastened” where the parts are connected in physical contact with each other. As used herein, two or more parts are said to be “rigidly coupled”, “rigidly connected”, “rigidly attached”, “rigidly joined”, “rigidly affixed”, or “rigidly fastened” where the parts are coupled so as to move as one while maintaining a constant orientation relative to each other. None of the terms “coupled”, “connected”, “attached”, “joined”, “affixed”, and “fastened” distinguish the manner in which two or more parts are joined together.

Further, although method steps may be described (in the disclosure and/or in the claims) in a sequential order, such methods may be configured to work in alternate orders. In other words, any sequence or order of steps that may be described does not necessarily indicate a requirement that the steps be performed in that order. The steps of methods described herein may be performed in any order that is practical. Further, some steps may be performed simultaneously.

As used herein and in the claims, a group of elements are said to ‘collectively’ perform an act where that act is performed by any one of the elements in the group, or performed cooperatively by two or more (or all) elements in the group.

As used herein and in the claims, a first element is said to be “received” in a second element where at least a portion of the first element is received in the second element unless specifically stated otherwise.

Some elements herein may be identified by a part number, which is composed of a base number followed by an alphabetical or subscript-numerical suffix (e.g., 112a, or 1121). Multiple elements herein may be identified by part numbers that share a base number in common and that differ by their suffixes (e.g., 1121, 1122, and 1123). All elements with a common base number may be referred to collectively or generically using the base number without a suffix (e.g., 112).

Conventional planar transformer structures are typically accompanied by three main challenges. First, conventional planar transformer structures have high inter/intra-winding parasitic capacitance due to high surface area. This causes common mode noise, voltage oscillations, and non-linear converter response especially at light loads, eventually leading to lower power efficiency.

Conventional planar transformers also have low inherent immunity to the proximity effect. To counteract this issue in planar transformers and reduce reduction losses, often strategies of careful interleaving of windings is employed, along with the use of multi-layered conductor arrangements ‘litzing’ and optimizing the winding geometry and configuration.

Another challenge associated with conventional planar transformers is higher leakage flux. This is because planar transformers generally have higher mean length per turn (MLT) than wire wound transformers for the same core volume. This can be compensated by higher interleaving of layers at which the planar transformer has outstanding automation capability.

In some cases, the above-noted challenges can be addressed by optimizing the winding geometry/structure of planar transformers, careful interleaving/arrangement of winding, and inserting shielding layers in-between isolated winding layers. This may provide the advantage of reducing the effective winding capacitance and improving the transformers' performance.

In some other cases, the above-noted challenges can be addressed by using active suppression methods to reduce dV/dt due to switching and hence the ringing voltage. In some other cases, the above-noted challenges can be addressed by optimizing other components surrounding the transformer as the gate resistance, and snubber capacitor to reduce dV/dt while also considering the shim inductor effect and placement.

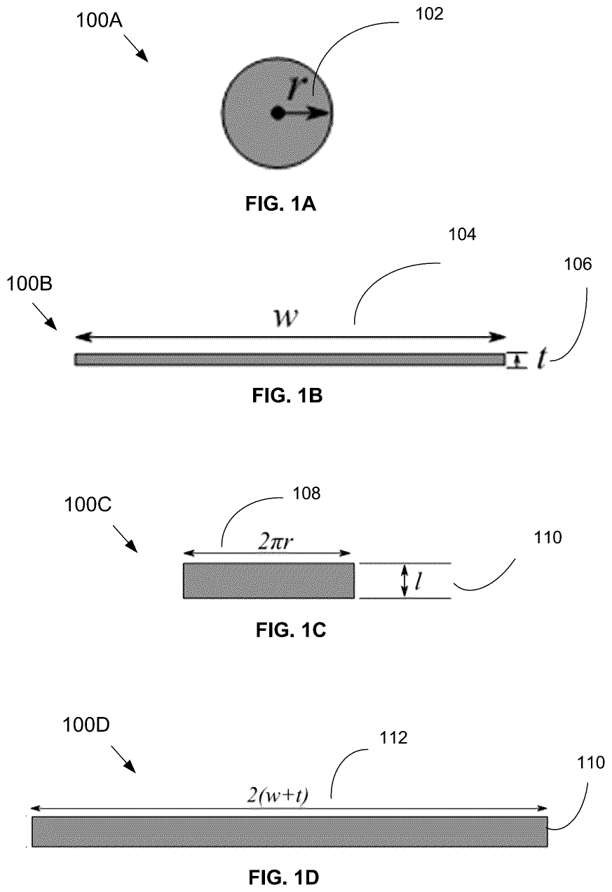

To illustrate the reason behind the high parasitic capacitance inherent in planar transformers, reference is made to FIGS. 1A-1D. FIG. 1A illustrates a round conductor 100A according to an example. FIG. 1B illustrates a flat planar conductor 100B according to an example with the same cross-sectional area (CSA) as the round conductor 100A. Round conductor 100A has a radius (r) 102, and CSA of πr². Planar conductor 100B has a width (ω) 104 and thickness (t) 106, and accordingly the CSA of ωt.

FIG. 1C illustrates the surface area 100C of the round conductor of FIG. 1A. FIG. 1D illustrates the surface area 100D of the planar conductor of FIG. 1B. For length (l) 110, the surface area 100C of the round conductor is 2πr, depicted by reference 108 and the surface area 100D of the planar conductor is 2(ω+t), depicted by reference 112. For the same CSA and length (l) 110, the planar conductor of FIG. 1D has a higher surface area, which leads to better thermal characteristics. For example, the planar conductor of FIG. 1D has lower thermal resistance, resulting in higher thermal dissipation.

A planar-type core has similarly high width to height aspect ratio compared to conventional wire wound core. Accordingly, at the same core volume, a planar core has a higher surface area, which contributes to its superior thermal performance.

In some cases, a planar conductor thickness (t) is constrained to twice the skin depth (δ), as formulated in equation (1), to avoid under-utilization of the used copper.

$$δ = \sqrt{\frac{ρ}{π {f}_{cycle} {μ}_{o} {μ}_{r}}} , t = 2 δ \qquad ( 1 )$$

In equation (1), p is the copper conductor resistivity, f_{cycle} is the cycle frequency of the current through the conductor, μₒ and μᵣ are the absolute and relative permeability of free space and copper respectively.

Equation (2) illustrates the surface area ratio (SAR) of the planar conductor to the round conductor.

$$SAR = \frac{{SA}_{p}}{{SA}_{r}} = \frac{ω + t}{π r} , r = \sqrt{\frac{ω t}{π}} \qquad ( 2 )$$

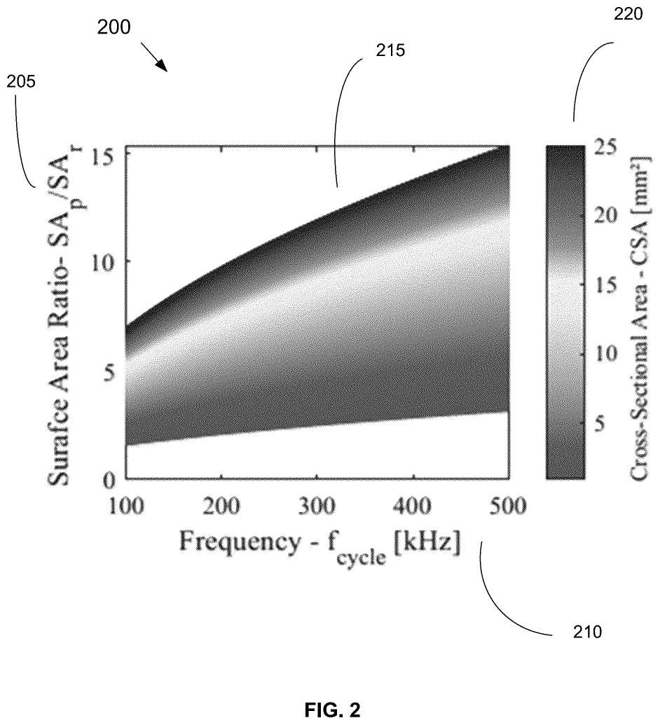

Reference is made to FIG. 2, which illustrates a plot 200 of surface area ratio between planar and round conductors, where the x-axis 210 depicts the cycle frequency (in KHz) of the current through the conductors, and the y-axis 205 depicts the surface area ratio of the planar conductor to the round conductor. Plot 200 also illustrates a z-axis depicting the CSA (in mm²). Plot 200 illustrates a graph 215 depicting that as the frequency increases, the SAR increases. Graph 215 also illustrates that as CSA increases, the SAR increases. However, a higher surface area ratio leads to higher overlapping area between the winding turns and potentially leads to higher parasitic capacitance, therefore limiting the use of a conventional planar transformer especially at higher frequencies or for higher current levels (higher CSA). It should be noted that conductor width, w, is also limited by the available core window width, number of turns in one layer and the clearance between turns.

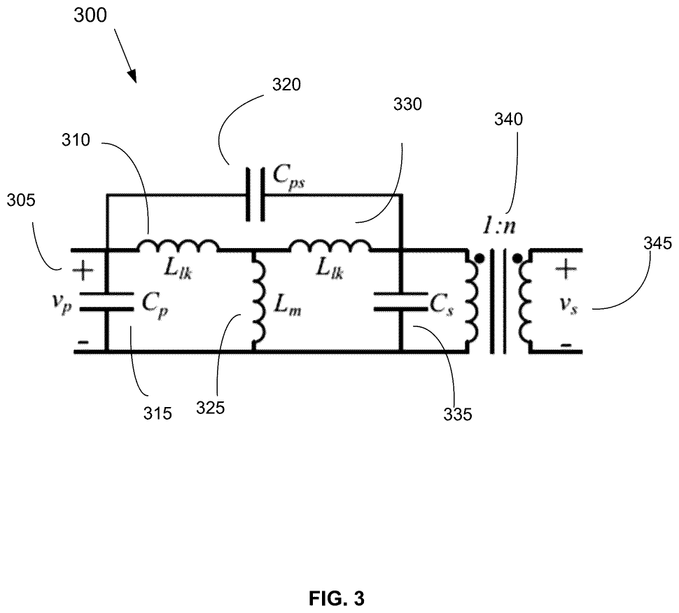

Reference is next made to FIG. 3, which illustrates an equivalent circuit model 300 for a two-winding transformer according to an example. FIG. 3 illustrates a primary winding voltage, vₚ, 305 and a secondary winding voltage, vₛ, 345. FIG. 3 also illustrates an inter-winding capacitance, Cₚₛ, 320, depicting the capacitance between isolated winding of a multi-winding transformer, and intra-winding capacitance, Cₚ, 315 and Cₛ, 335, referring to capacitance between the turns inside the primary and secondary windings, respectively. FIG. 3 also shows a first transformer leakage inductance, Lᵢₖ, 310, a second transformer leakage inductance, Lᵢₖ, 330, and a magnetizing inductance, Lₘ, 325. The secondary to primary transformer turns ratio, n, is depicted by reference number 340.

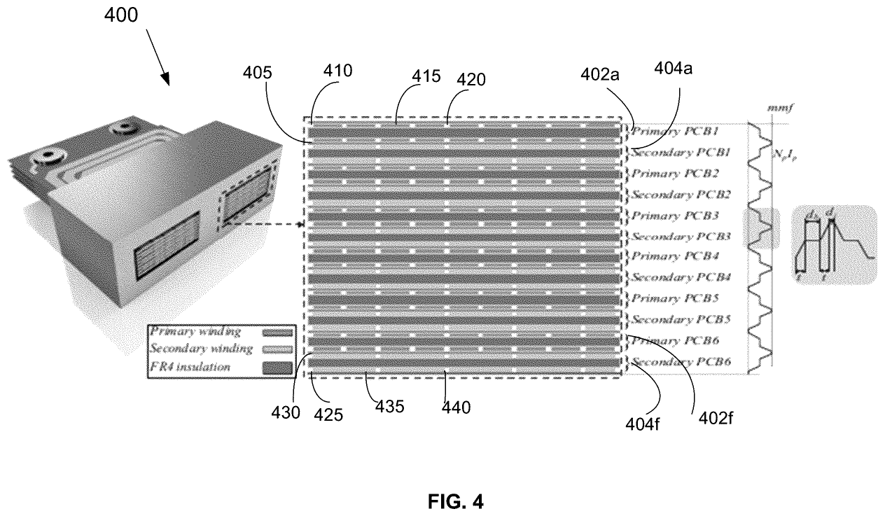

Reference is next made to FIG. 4, which illustrates a conventional fully interleaved structure 400 of a planar transformer. The illustrated planar transformer comprises six interleaved board pairs (m=6), where the primary PCBs, 402, are connected in parallel to each other as well as to the secondary PCBs, 404.

Each primary PCB, such as PCB 402a, consists of a bottom 405 and a top 410 layer. As shown, the bottom and the top layers of a primary PCB consist of 9 number of turns 415 on each side. The turns 415 on the top and bottom layers are connected in series through a VIA 420 to get a total number of 18 turns per board (Nₚ=18). Since this transformer turns ratio (n) is 0.5, the number of turns 435 for each secondary board, such as PCB 404f, is 9 (Nₛ=9) and are divided between the top 430 and bottom 435 layers of the secondary PCB.

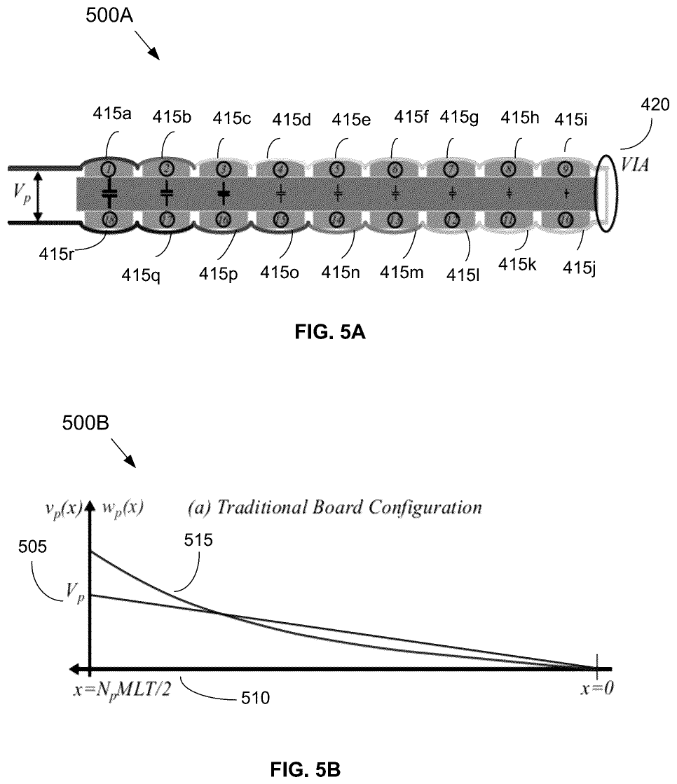

Reference is next made to FIG. 5A, which illustrates an example winding configuration 500A of a conventional planar transformer. As illustrated, each turn 415 on the top layer is connected in series with adjacent turn 415. For example, the first turn 415a is connected in series with turn 415b, which is connected in series with turn 415c, and so on. Turns 415a to 415i are connected in series on the top layer. Further, as illustrated, top layer turn 415i is connected in series with the bottom layer turn 415j through a single via 420. Turns 415j to 415r are also connected in series on the bottom layer.

FIG. 5B illustrates the electrostatic energy analysis plot 500B of the planar transformer with winding arrangement of FIG. 5A. Plot 500B shows a graph 505 of vₚ (x), representing the voltage difference between each two vertically opposite points on the bottom and top layers as a function of x, 510, which represents the distance between the winding mid-point to the winding ends which is L and is equal to half the mean length per turn (MLT) multiplied by Nₚ. d_{b} is the PCB core thickness and di is the insulation sheet thickness inserted in-between the primary and secondary boards.

As seen in FIG. 5B, if a positive input voltage with peak, Vₚ, is applied on the winding terminals, a linear voltage distribution across the turns is seen. Also seen in FIG. 5B is a plot 515 of electrostatic field energy, wₚ (x), as a function of distance, x.

The energy stored in the dielectric insulation between opposite turns is significantly larger compared to the one stored between adjacent turns on the same layer due to much higher overlapping area and effective capacitance. Therefore, the capacitance between adjacent turns can be neglected.

Assuming uniform surface charge density distribution on the winding, the primary winding voltage, vₚ, changes linearly with respect to distance x along with the electric field through the FR4 insulation which results in a quadratic rise of the electrostatic field energy (wₚ) stored inside the dielectric FR4 material according to equation (3), and assuming Nₚ>2.

$${w}_{p} = \frac{1}{2} \frac{{ε}_{o} {ε}_{r} {t}_{ω} dx}{{d}_{b}} {v}_{p}^{2} ( x ) , {v}_{p} ( x ) = \frac{{xV}_{p}}{L} \qquad ( 3 )$$

t_{w} is the copper trace width, εₒ and εᵣ are the absolute and relative permittivity of free space and FR4 respectively.

The total stored energy in the dielectric FR4 (Wₚ) and the equivalent capacitance (C_{trad}) can be calculated by equations (4) and (5), respectively.

$${W}_{p} = {\int }_{0}^{L} {w}_{p} = \frac{1}{12} \frac{{ε}_{o} {ε}_{r} {t}_{ω}}{{d}_{b}} {N}_{p} {MLTV}_{p}^{2} \qquad ( 4 )$$

$${C}_{trad , op .} = \frac{1}{6} \frac{{ε}_{o} {ε}_{r} {t}_{ω}}{{d}_{b}} {N}_{p} MLT \qquad ( 5 )$$

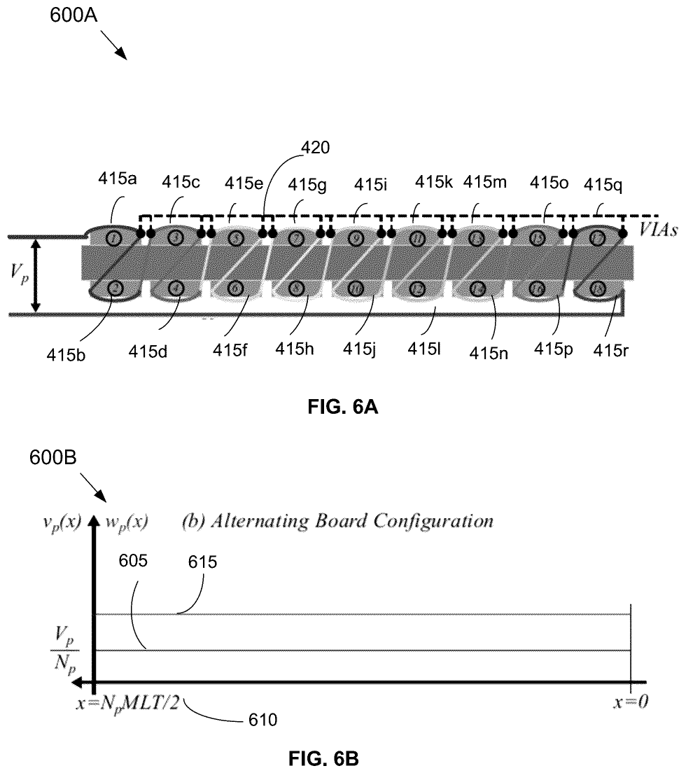

Reference is next made to FIG. 6A, which illustrates an alternating winding configuration 600A for a planar transformer. This configuration is achieved by alternating between the top and bottom layers after each turn 415 such that opposite turns are successive. For example, as illustrated, turn 415a on top layer is connected to turn 415b on bottom layer, which is connected to turn 415c on top layer, and so on. In this configuration, multiple vias 420 are required.

FIG. 6B illustrates the graphical representation 600B of electrostatic energy analysis of the planar transformer with winding arrangement of FIG. 6A. As seen, plot 605 illustrates a constant voltage difference for opposing turns of Vₚ/Nₚ, which results in a constant electrostatic energy for any given distance, x, as shown by plot 615.

In this alternating winding configuration, lower intra-winding capacitance is achieved. In some cases, the intra-winding capacitance is reduced by a factor of 3/Np² This configuration results in a constant lower voltage difference of Vₚ/Nₚ (assuming even Nₚ and uniform surface charge density) as seen in equation (6).

$${w}_{p} = \frac{1}{2} \frac{{ε}_{o} {ε}_{r} {t}_{ω} dx}{{d}_{b}} {v}_{p}^{2} ( x ) , {v}_{p} ( x ) = \frac{{V}_{p}}{{N}_{p}} \qquad ( 6 )$$

Wₚ and Cₐₗₜ are calculated by equations (7) and (8), respectively.

$${W}_{p} = {\int }_{0}^{L} {w}_{p} = \frac{1}{12} \frac{{ε}_{o} {ε}_{r} {t}_{ω}}{{d}_{b}} {N}_{p} {MLTV}_{p}^{2} ( \frac{3}{{N}_{p}^{2}} ) \qquad ( 7 )$$

$${C}_{alt , op .} = \frac{1}{6} \frac{{ε}_{o} {ε}_{r} {t}_{ω}}{{d}_{b}} {N}_{p} MLT ( \frac{3}{{N}_{p}^{2}} ) \qquad ( 8 )$$

Non-uniform charge density can occur in the case of having small gaps between adjacent turns causing high concentration in the electric-field through the dielectric. In this case, Cₐᵢₜ can increase by a factor four due to uneven charge density along the track width, so instead the factor can reach 12/Nₚ². In addition, the inter-winding capacitance is not optimized, which can cause significant common mode current and electromagnetic interference (EMI) issues if left unchecked.

In some cases, the effective inter-winding capacitance can be minimized to minimize the common mode noise and achieve near zero common mode current. In some cases, the planar transformer involves strategic interleaving certain turns of the primary and secondary winding together which have similar voltage magnitudes to achieve close to zero potential between the two-winding interface layer. However, such a technique is only effective for specific values of turns ratio and causes lower copper utilization to avoid overlapping of secondary and primary turns of different potentials and requires the use of less economic multi-layer PCBs. As such, the alternating current (ac) copper loss and efficiency of the transformer varies considerably depending on the transformer turns ratio and might not be feasible in certain applications.

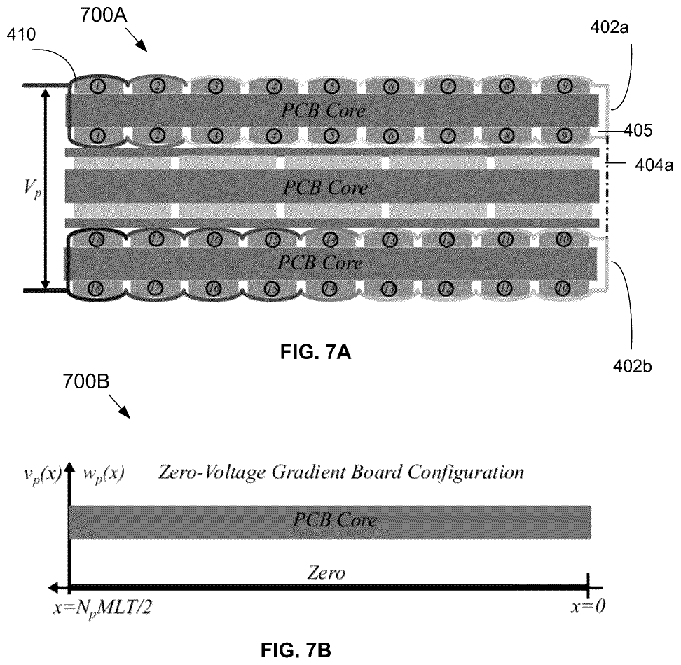

In some other cases, the minimal intra-winding capacitance of each board is achieved by connecting opposite turns on the top 410 and bottom 405 layers of a primary PCB 402a in parallel, as shown in FIG. 7A. In such a transformer configuration, a zero-voltage gradient (ZVG) across each board winding is achieved, as shown in FIG. 7B. Electrostatic field energy (wₚ) is calculated based on equation (9).

$${w}_{p} = \frac{1}{2} \frac{{ε}_{o} {ε}_{r} {t}_{ω} dx}{{d}_{b}} {v}_{p}^{2} ( x ) , {v}_{p} ( x ) \approx 0 \qquad ( 9 )$$

However, the inter-winding capacitance was not optimized and relies heavily on the use of air separation (reducing insulation capability) and even number of interleaving layers for both the primary and secondary winding.

In some other cases, solutions focused on inter-winding capacitance effects mitigation and EMI suppression, but did not take into account the converter non-linear response that may rise due to the intra-winding capacitance across the winding terminals especially at higher frequencies or light load operations which can cause high voltage oscillations.

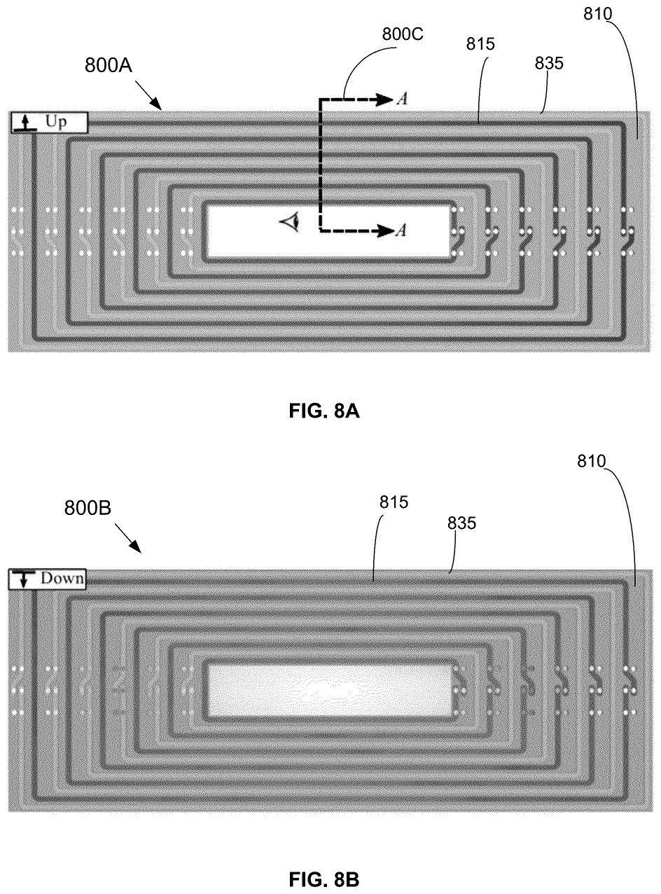

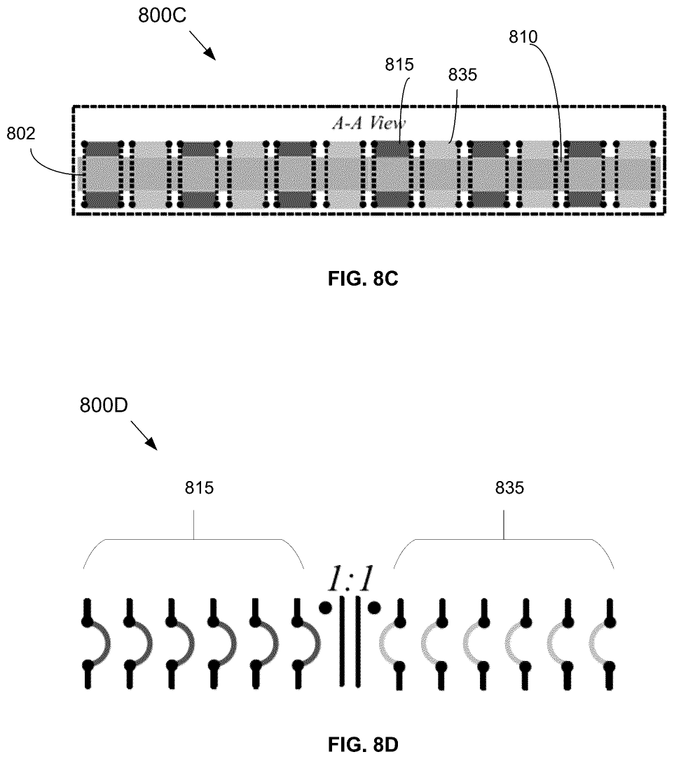

Disclosed in the various embodiments herein is an improved co-planar transformer configuration. An example of a co-planar transformer, with a two-layer PCB, is shown in FIGS. 8A-8B. FIG. 8A shows a view 800A when the PCB is face-up, and FIG. 8B shows a view 800B when the PCB is face-down. As illustrated in FIGS. 8A and 8B, the copper turns on the top and bottom layers of the PCB are duplicated.

As illustrated in FIG. 8C, which shows the sectional A-A view 800C of FIG. 8A, each turn end on the top-layer is connected in parallel with the opposite turn on the bottom layer through VIAs. Also, as shown, the interleaving between the primary winding 815 and secondary winding 835 is done horizontally along the board surface instead of interleaving multiple stacked boards. In this configuration, only a single main board design, i.e. one PCB 810, is needed for both the primary and secondary winding instead of two different main board designs for each winding compared to other planar transformers.

By winding both the primary 815 and secondary 835 turns on the same board 810, the overlap area between primary and secondary turns is minimized. In such cases, almost only the adjacent surface area contributes to the capacitance between the primary and secondary winding. Since the copper trace thickness is significantly lower compared to the trace width, this results in a significant decrease of inter-winding capacitance between the primary and secondary winding. At the same time, by having the top and bottom opposite turns of each winding connected in parallel, as shown by reference number 802, there is zero voltage across opposite turns and hence electrostatic energy in each board is reduced. This provides the advantage of a substantial reduction in the intra-winding capacitance.

In configurations where both the primary and secondary turns share the same board, careful selection of turn-to-turn clearance, conformal coating, and cut-out regions is needed to ensure a proper isolation barrier. As the required isolation voltage and turn-to-turn clearance increases, the number of interleaving layers (m) which fits inside the width of the considered core window decreases.

In some cases, for the co-planar transformer configuration discussed above, the basic insulation level (BIL) is selected for a maximum working voltage of 800V, which corresponds to a dielectric insulation layer with a minimum breakdown voltage of 16 kV. For such constraints, the coating of turns can be done using a 422B dielectric material with a withstand voltage of 41.5 kV/mm and a turn-to-turn coating of 0.7 mm. In such cases, a theoretical withstand voltage of 29 kV is achieved which leaves more than 180% of safety margin for aging and non-uniform coating. The terminals or conductors are placed on opposite side of the board thus meeting the harshest clearance and creepage distance required through air which are 32 and 25 mm respectively for reinforced insulation with a pollution degree 3.

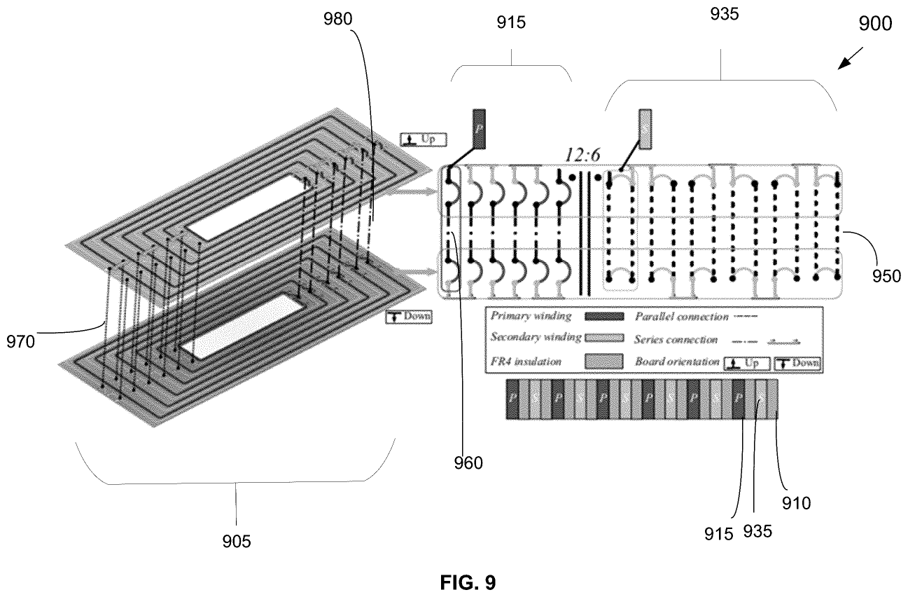

Reference is next made to FIG. 9, which illustrates another co-planar transformer configuration 900. To increase the current carrying capability and compensate for the larger turn-to-turn clearance of the co-planar transformer configuration of FIGS. 8A-8B, more boards are added in the co-planar transformer configuration of FIG. 9. The boards are connected in parallel to share the current. Since any boards added in parallel has the same structure and zero voltage gradient, the opposite intra winding capacitance does not increase and no added insulation is needed in-between. Lower insulation material allows the addition of higher number of boards along the core window height compared to other types of planar transformers.

FIG. 9A illustrates a two-board stack, As shown, the facing-up primary winding turns 915 are connected in series 960 with the facing-down primary winding turns 915. In some cases, the series connection is made through soldered copper rods 970 passing through opposite pads. On the other hand, the facing up secondary winding turns 935 are connected in parallel 950 to the facing down secondary winding turns 935. In some cases, to make a parallel connection for the secondary turns, connection rods 980 can be inserted through the parallel pads.

An advantage of such a board design is the flexibility to have either parallel or series connection for the primary or secondary winding independently. Depending on the required turns ratio, the type of vertical connection between the different turns can be changed. In addition, for a higher number of turns, a similar structure can be developed to have the board designed with multiple turns in series of the same winding while alternating between the top and bottom layers, to have, for example, 12 turns per board instead of 6.

Further, the intra-winding capacitance is also reduced significantly since now opposite turns of the same winding have low voltage potential difference since opposite turns of different boards are either connected in parallel, so they have zero voltage potential, or connected in series so they have low voltage potential which is the per turn voltage.

Table I shows an example of a co-planar transformer configuration based on the disclosure herein.

TABLE I
Transformer Specifications

| Transformer Parameter | Value | |
|---|---|---|
| Primary/Secondary Voltage Rating | 800/400 | V |
| Primary Turns:Secondary Turns | 18:9 | |
| Switching Frequency | 100 | kHz |
| Rated Power | 5 | kW |
| Ferrite Core | TDK-EELP 64-N97 | |
| Copper Layer Thickness | 4 | oz |
| Finished PCB Board Thickness | 0.7 | mm |

| | |
|---|---|
| Interleaved Layers | 6 |

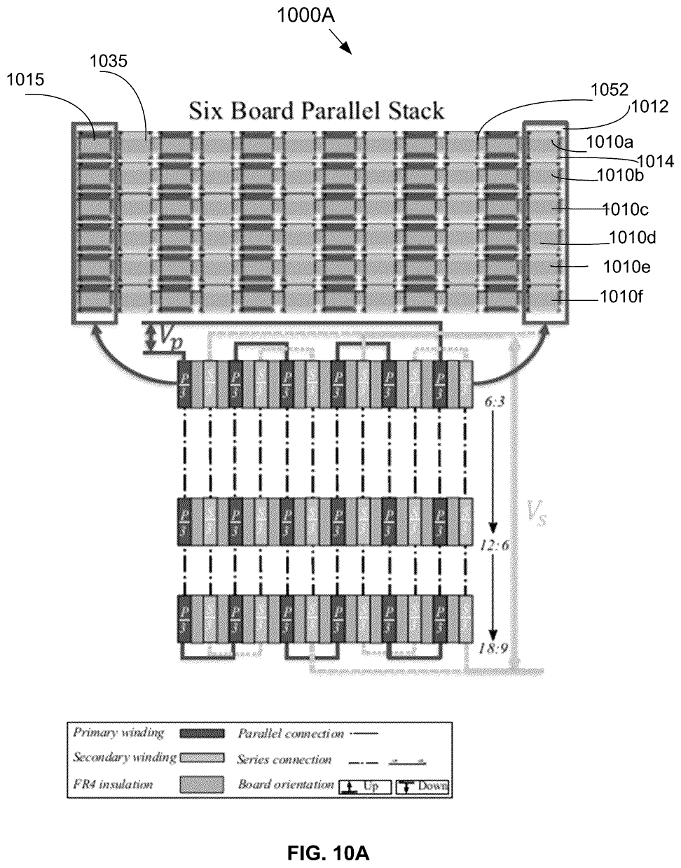

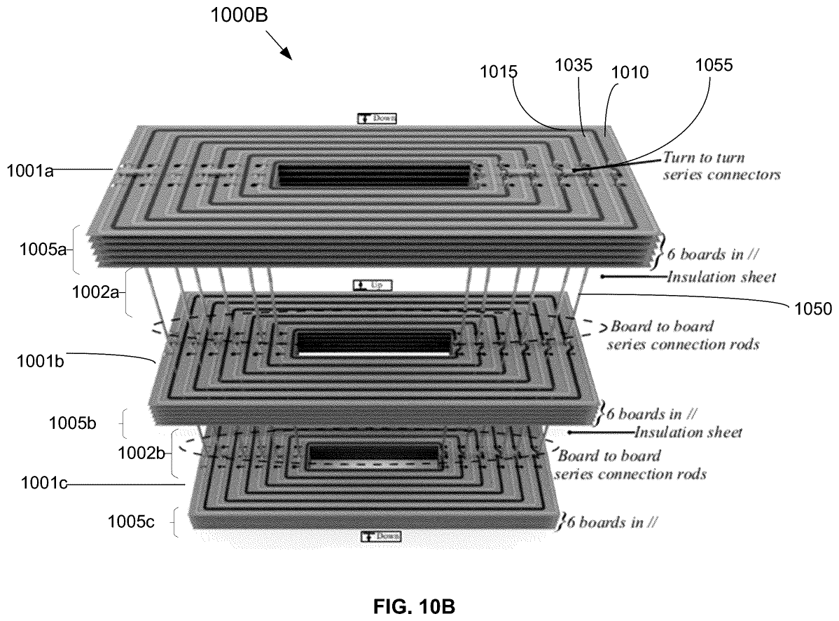

Reference is next made to FIGS. 10A-10B, which illustrate another example of a co-planar transformer configuration. FIG. 10A illustrates the winding configuration 1000A of the co-planar transformer. FIG. 10B illustrates a schematic view 1000B of the full stack of the co-planar transformer.

In this embodiment, as shown in FIG. 10B, the co-planar transformer consists of 3 stacks with each stack containing 6 boards connected in parallel (see, boards 1010a . . . 1010f shown in FIG. 10A). For example, stack 1001a consists of 6 boards 1005a, stack 1001b consists of 6 boards 1005b and stack 1001c consists of 6 boards 1005c. The interconnection of each stack in FIG. 10A shows that each board consists of six interleaved turns for each of the primary and secondary winding. Accordingly, the co-planar transformer 1000A, 1000B consists of 18 stacked boards. The stacks are connected in series to each other.

As shown in FIG. 10A, the boards within each stack are connected in parallel to each other. The board consists of six interleaved turns for each of the primary 1015 and secondary 1035 windings. As shown, the top 1012 and the bottom 1014 turns in each board, such as board 1010a, are mirrored about the board plane and are connected in parallel 1052 through VIAs.

To connect two consecutive boards or stacks in series, the two board or stacks are placed in opposite orientations to maintain the direction of current circulation for field production. The series connection between turns is made using soldered copper rods 1050, connecting the end terminal via of one turn to the start terminal via of the next turn.

Next, the electric (\vec{E}) and displacement (\vec{D}) fields for a given winding stack's 3D geometry is discussed to assess the electrostatic energy field stored in the stack (Wₜ) for parasitic capacitance estimation. Further, evaluating the electric field concentration and strength can help to avoid insulation breakdown of a given design. After developing the 3D model for a given winding stack, the geometry is assessed using a tool, such as Ansys Maxwell-Electrostatic. In a tool like this, material properties are defined and excitation voltage is applied on the winding terminals. The applied excitation voltage for each winding changes which part of the winding capacitance is analyzed. For example, applying Vₚ on the primary winding terminals and nVₚ on the secondary side will result in a total energy of the three capacitors shown in the three-capacitor equivalent model, as shown in FIG. 3. Further, mesh of the model is refined until the solution converges to an acceptable energy error level. In some cases, a minimum mesh size of 1 million meets the convergence criteria for a mesh size that is quarter 3D slice of the stack.

The same applied voltage excitation across the winding ends needs to be used for fair energy density comparison between the different winding configurations. The applied voltage generates an electric and displacement field which can be used to calculate the total electrostatic energy (Wₜ) stored inside the considered winding stack as seen in equation (10), where Vol. is the total volume of the stack.

$${W}_{t} = \frac{1}{2} {∮}_{Vol .} \vec{E} \cdot \vec{D} dv \qquad ( 10 )$$

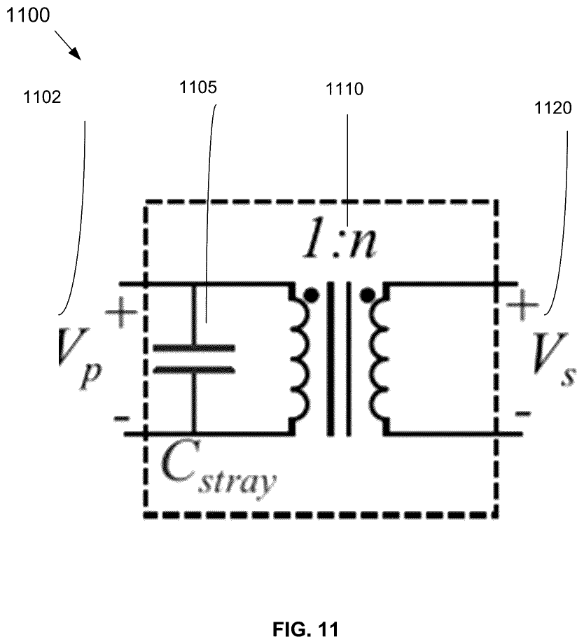

FIG. 11 illustrates a simplified equivalent one capacitor (C_{stray}) transformer model 1100. In particular, FIG. 11 illustrates a primary winding voltage, vₚ, 1102 and a secondary winding voltage, vₛ, 1120. FIG. 3 also illustrates a stray capacitor, C_{stray}, 1105, in parallel to the primary winding voltage. The secondary to primary transformer turns ratio, n, is depicted by reference number 1110.

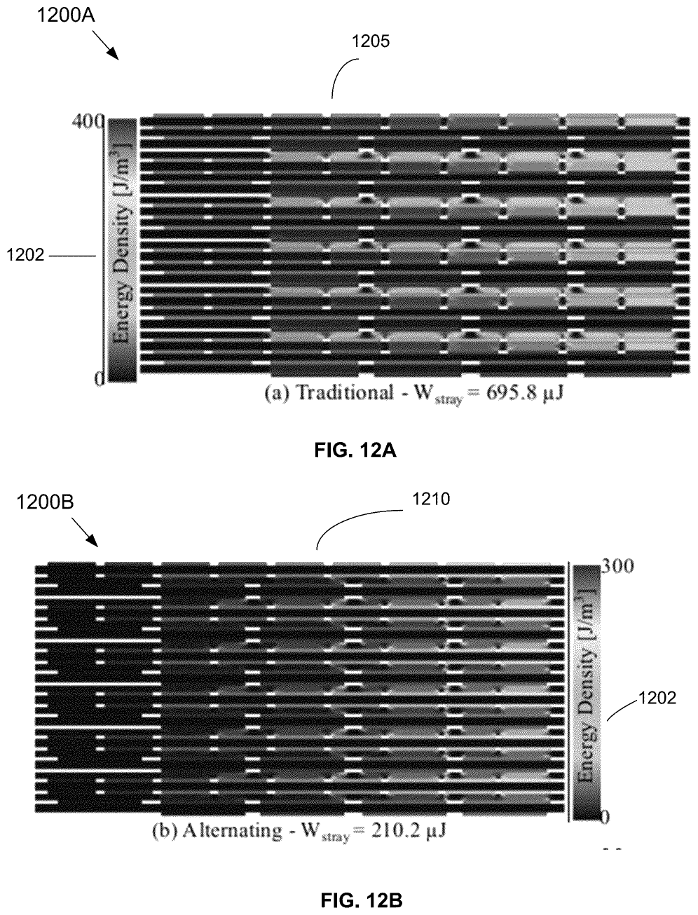

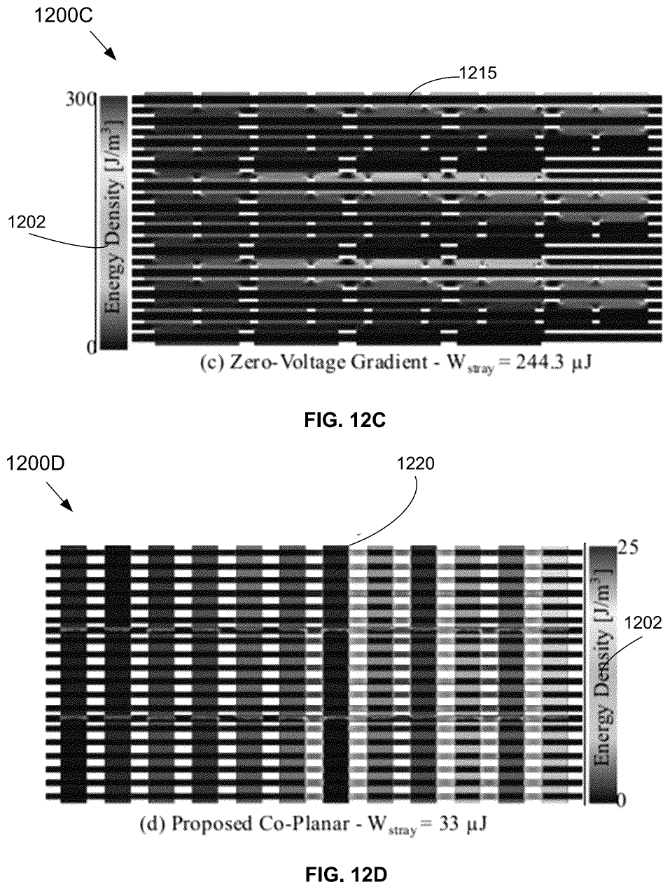

The model 1100 can be used to compare between various transformer configurations and reduce simulation effort that evaluates each capacitor independently by applying super position. Next, according to the stray energy model 1100, the same voltage has been applied on the primary 1102 and secondary 1120 winding for all transformer configurations and the resulting energy density has been plotted in FIGS. 12A-12D.

Reference is next made to FIGS. 12-12D, which illustrate the energy density response (measured in J/m³) for various transformer configurations inside same core window. The energy density fields are plotted for the FR4 insulation layers and voltage fields for the copper winding. For the plots of FIGS. 12A-12D, the rated voltage is applied at the winding end terminals for all transformer configurations, which each transformer comprising characteristics of: Vₚ=800V, Vₛ=400V, Nₚ=18, Nₛ=9, m=6, t=4 oz.

FIG. 12A illustrates a plot 1205 of the electrostatic energy density response 1202 of a traditional planar transformer. FIG. 12B illustrates a plot 1210 of the electrostatic energy density response 1202 of a planar transformer with alternating winding configuration, such as that discussed in relation to FIG. 6A. FIG. 12C illustrates a plot 1215 of the electrostatic energy density response 1202 of a planar transformer with zero-voltage gradient winding configuration, such as that discussed in relation to FIG. 7A. FIG. 12D illustrates a plot 1220 of the electrostatic energy density response 1202 of a planar transformer with the co-planar transformer configuration disclosed herein.

As seen, for the same core window dimension for all transformer configurations in FIGS. 12A-12D, and the same voltage amplitude, the energy density field is much higher in the traditional transformer configuration in FIG. 12A due to the high voltage gradient which generates a correspondingly high electric and displacement fields.

On the other hand, FIG. 12D shows significantly lower voltage gradient and hence lower total electrostatic energy Wₜ reaching 21 times reduction compared to the traditional configuration of FIG. 12A, and 6 times lower compared to the closest configurations of alternating and ZVG as seen in FIGS. 12B and C, respectively.

Next, to ensure that the transformer efficiency is not compromised, 2D FEA analysis of the various transformer configurations is carried out to evaluate the transformer' total copper loss and core loss under the same ideal excitation conditions. An analysis tool, such as Ansys Maxwell, can be used for such an analysis.

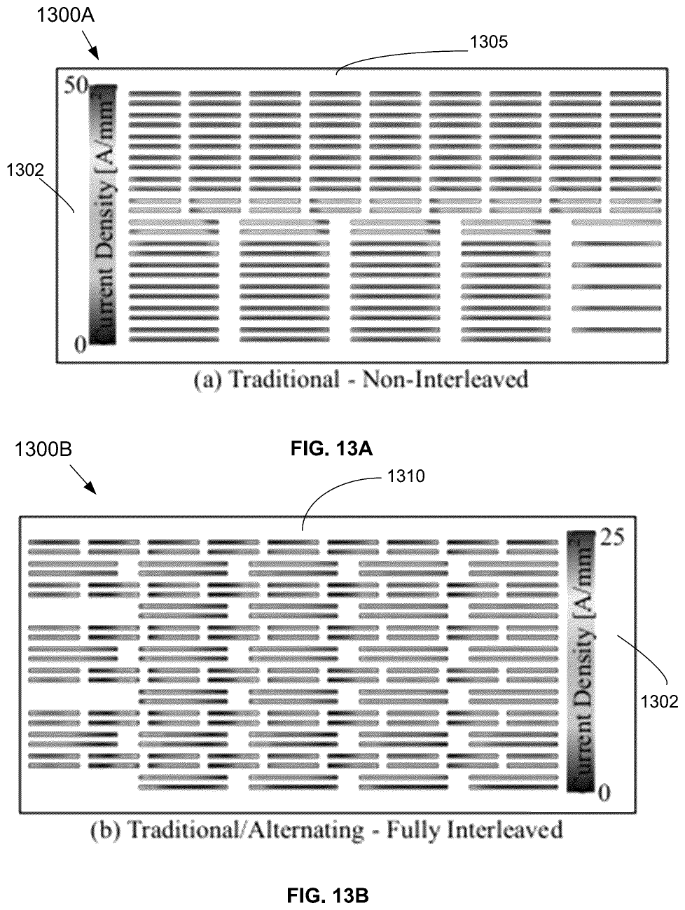

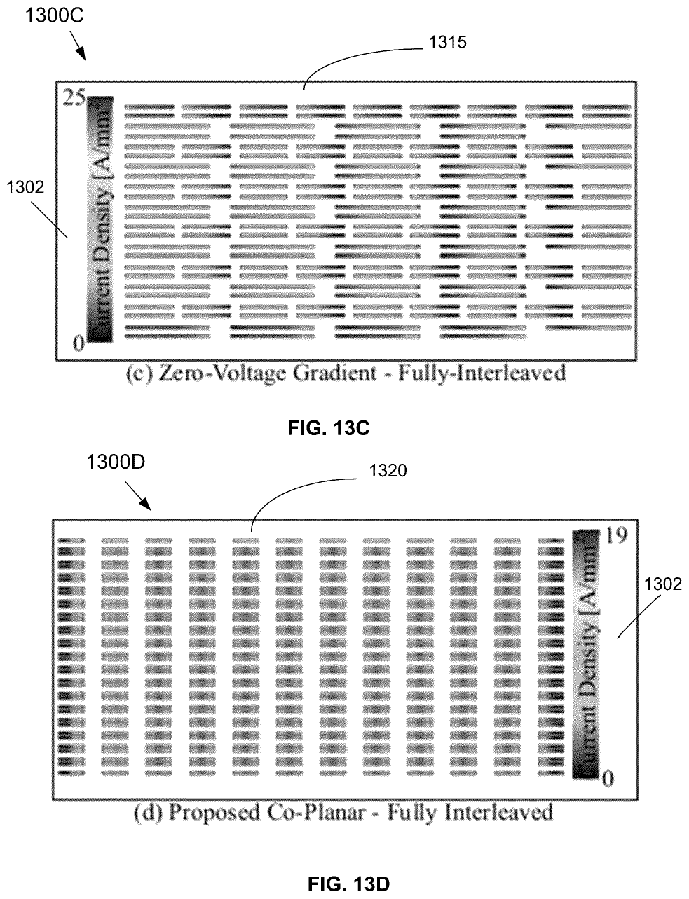

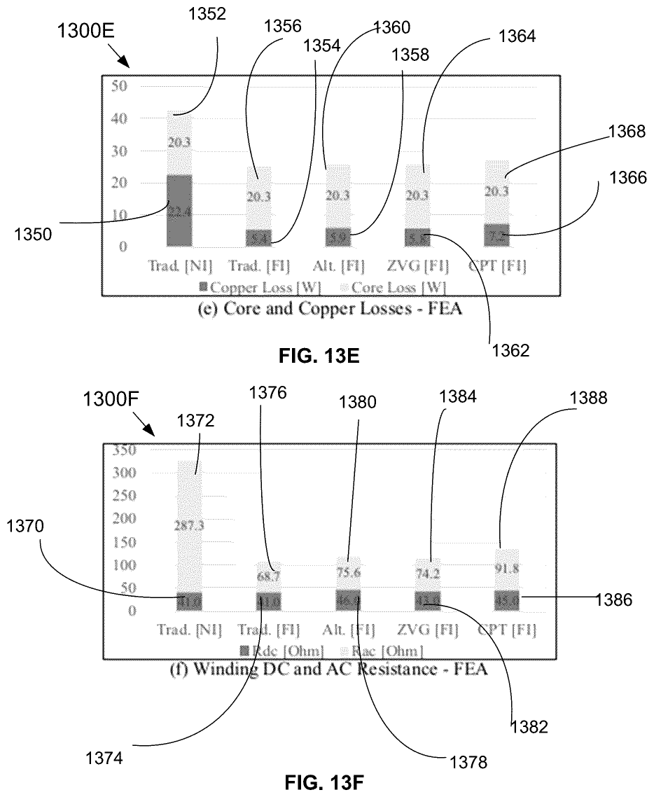

The copper winding stack of each configuration seen from inside the core window is analyzed and peak current density field plots of each winding configuration is shown in FIGS. 13A-13D. To generate these plots, the rated sinusoidal current is applied for all transformer configurations, where the primary current, Iₚ=6.25 Arms, secondary current, Iₛ=12.5 Arms, f=100 kHz, Nₚ=18, Nₛ=9, m=6, t=4 oz.

FIG. 13A illustrates a plot 1305 of the current density response 1302 of a traditional non-interleaved transformer configuration. FIG. 13B illustrates a plot 1310 of the current density response 1302 of a transformer with alternating winding configuration, such as that discussed in relation to FIG. 6A. FIG. 13C illustrates a plot 1315 of the current density response 1302 of a planar transformer with zero-voltage gradient winding configuration, such as that discussed in relation to FIG. 7A. FIG. 13D illustrates a plot 1320 of the current density response 1302 of a transformer with the co-planar transformer configuration disclosed herein.

As shown in FIGS. 13A-13D, for the traditional non-interleaved arrangement, the peak current density is almost double compared to the fully-interleaved structures shown in FIGS. 13B-13D, since proximity affect is substantially reduced. The core losses under ideal excitation are the same for all configuration due to having the same excitation voltage, core size, and number of turns.

FIG. 13E illustrates the copper loss and core loss measurements 1300E for the various transformer configurations. In particular, plot 1350 refers to the copper loss measurements for a traditional non-interleaved transformer configuration. Plot 1354 refers to the copper loss measurements for a traditional fully interleaved transformer configuration. Plot 1358 refers to the copper loss measurements for an alternating fully interleaved transformer configuration. Plot 1362 refers to the copper loss measurements for a zero-voltage gradient fully interleaved transformer configuration. Plot 1366 refers to the copper loss measurements for a co-planar transformer configuration.

Plot 1352 refers to the core loss measurements for a traditional non-interleaved transformer configuration. Plot 1356 refers to the core loss measurements for a traditional fully interleaved transformer configuration. Plot 1360 refers to the core loss measurements for an alternating fully interleaved transformer configuration. Plot 1364 refers to the core loss measurements for a zero-voltage gradient fully interleaved transformer configuration. Plot 1368 refers to the core loss measurements for a co-planar transformer configuration.

The total core and copper losses of each configuration plotted in FIG. 13E shows that traditional non-interleaved copper losses are significantly higher compared to interleaved structures. The difference in losses between other structures is minute and mainly due to different winding MLT and gap sizes between the interleaved layers.

FIG. 13F illustrates the winding DC and AC resistance measurements 1300F for the various transformer configurations. In particular, plot 1370 refers to the DC resistance measurements for a traditional non-interleaved transformer configuration. Plot 1374 refers to the DC resistance measurements for a traditional fully interleaved transformer configuration. Plot 1378 refers to the DC resistance measurements for an alternating fully interleaved transformer configuration. Plot 1382 refers to the DC resistance measurements for a zero-voltage gradient fully interleaved transformer configuration. Plot 1386 refers to the DC resistance measurements for a co-planar transformer configuration.

Plot 1372 refers to the AC resistance measurements for a traditional non-interleaved transformer configuration. Plot 1376 refers to the AC resistance measurements for a traditional fully interleaved transformer configuration. Plot 1380 refers to the AC resistance measurements for an alternating fully interleaved transformer configuration. Plot 1384 refers to the AC resistance measurements for a zero-voltage gradient fully interleaved transformer configuration. Plot 1388 refers to the AC resistance measurements for a co-planar transformer configuration.

The AC and DC resistance extracted from FEA analysis of the different configurations plotted in FIG. 13F shows very close DC resistance to the lower resistance configuration while higher AC resistance due to increased proximity effect arising from the increased gaps between the interleaved layers. The electromagnetic loss analysis was done under ideal sinusoidal excitation not taking into account the voltage/current oscillations due to the parasitic capacitance network which contributes heavily to increased core and conduction losses, as discussed below.

### Experimental Verification

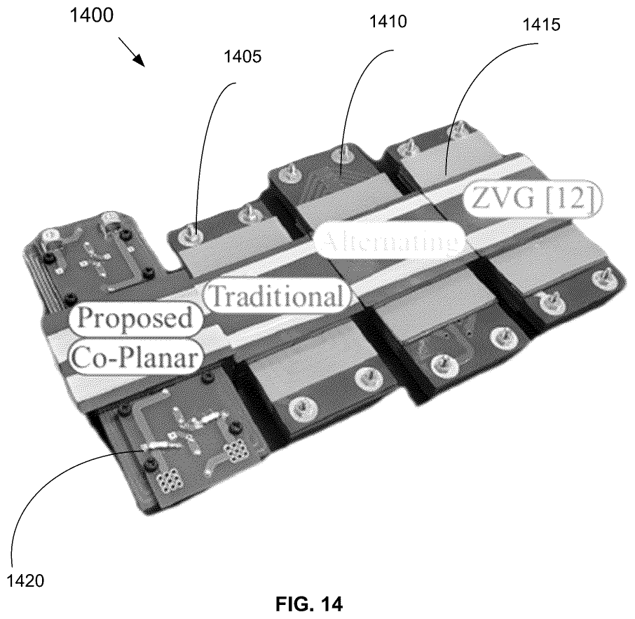

Reference is next made to FIG. 14, which shows various planar transformer configurations 1400 that have been setup for experimental validation. As shown, the first transformer configuration 1405 is a traditional configuration. The second transformer configuration 1410 is an alternating fully interleaved configuration. The third transformer configuration 1415 is a zero-voltage gradient interleaved configuration. The fourth transformer configuration 1420 is a co-planar fully interleaved transformer configuration.

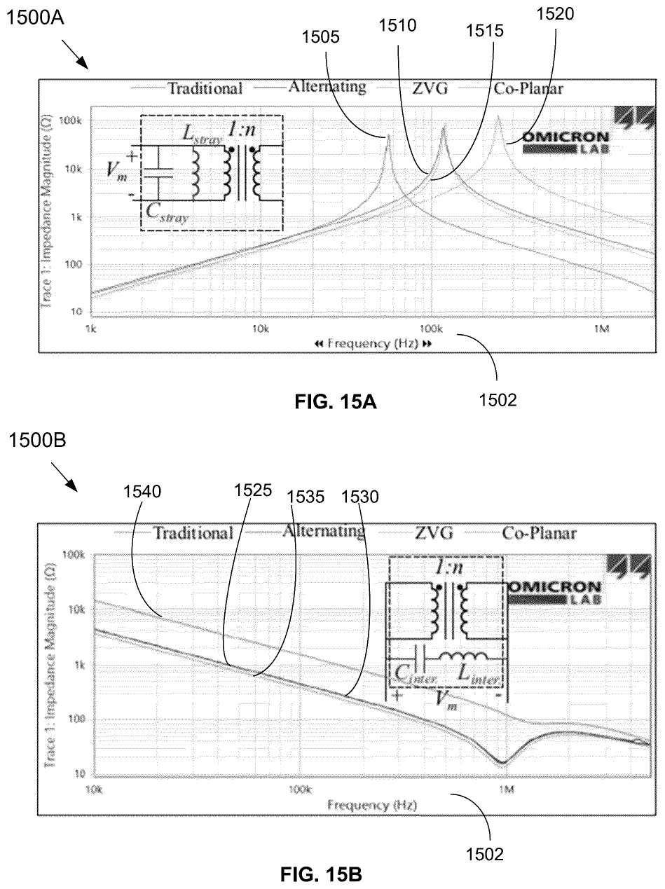

Next, reference is made to FIGS. 15A-15B, which illustrate the impedance testing of the four transformer configurations of FIG. 14. In the present embodiment, the four planar transformers are tested using the Bode 100 network analyzer from Omicron Labs. Several tests were performed to measure the effective voltage gain and winding impedance frequency response. Based on the experiment, the voltage gain measurement of all planar transformers 1400 confirmed that all four had a settling voltage gain of 0.5. This was expected since this is equal to the specified turns ratio n.

Three main impedance tests were done on each transformer configuration to measure: i) the equivalent stray capacitance (C_{stray}) across the primary winding; ii) the inter-winding capacitance (Cᵢₙₜₑᵣ) between the primary and secondary winding; and iii) the total leakage inductance measured on the primary winding which the secondary winding was shorted.

The leakage inductance measured on the primary side for the various planar transformer configurations are shown in table II below:

TABLE II
Measured Leakage Inductance at Primary Side

| | Total leakage |
|---|---|
| Winding Configuration | inductance |
| Traditional configuration 1405 | 1.4 μH |
| Alternating configuration 1410 | 1.6 μH |
| Zero-voltage gradient configuration 1415 | 1.5 μH |
| Co-planar transformer configuration 1420 | 1.9 μH |

As seen in Table II, the leakage inductance of the co-planar transformer configuration is slightly higher due to a higher inter-winding clearance and mean length per turn (MLT), but can potentially reduce the external shim inductor size.

For experimental validation, the same shim inductor (Lₛₕᵢₘ=20 μH) is used for the various planar transformer configurations 1400 under test. The selected shim inductor is higher compared to leakage inductance. The high shim to leakage inductance ratio is typical for a fully interleaved high frequency transformer and highlights the converter response due to difference in winding capacitance.

Reference is made to FIG. 15A, which illustrates a graphical representation 1500A of the stray capacitance (C_{stray}) measurements across the primary terminals of the four planar transformers, while the secondary terminal is open circuit. Plot 1505 shows the stray capacitance measurement across the primary terminals of a traditional planar transformer, such as transformer 1405, as a function of frequency 1502. Plot 1510 shows the stray capacitance measurement across the primary terminals of an alternating configuration planar transformer, such as transformer 1410, as a function of frequency 1502. Plot 1515 shows the stray capacitance measurement across the primary terminals of a zero-voltage gradient configuration transformer, such as transformer 1415, as a function of frequency 1502. Plot 1520 shows the stray capacitance measurement across the primary terminals of a co-planar configuration transformer, such as transformer 1420, as a function of frequency 1502.

As shown, the frequency 1502 is swept from 1 KHz up to 2 MHZ, and the co-planar transformer has the highest resonant frequency, as depicted by plot 1520. This translates to lower stray capacitance due to having almost the same magnetizing inductance (Lₘ) with minute difference due to assembly tolerance which can be neglected. Here, Lₘ is approximately equal to the stray inductance (L_{stray}) since the leakage inductance is relatively much lower and can be ignored.

Reference is made to FIG. 15B, which illustrates a graphical representation 1500B of the inter-winding capacitance (Cᵢₙₜₑᵣ) measurements between the shorted primary and secondary windings. Plot 1525 shows the inter-winding capacitance measurement of a traditional planar transformer, such as transformer 1405, as a function of frequency 1502. Plot 1530 shows the inter-winding capacitance measurement of an alternating configuration planar transformer, such as transformer 1410, as a function of frequency 1502. Plot 1535 shows the inter-winding capacitance measurement of a zero-voltage gradient configuration transformer, such as transformer 1415, as a function of frequency 1502. Plot 1540 shows the inter-winding capacitance measurement of a co-planar configuration transformer, such as transformer 1420, as a function of frequency 1502.

As shown, the impedance of the co-planar transformer is much higher especially near to the switching frequency, as depicted by plot 1540. This translates to a higher inter-winding impedance path due to a lower inter-winding capacitance, thus reducing the common mode noise.

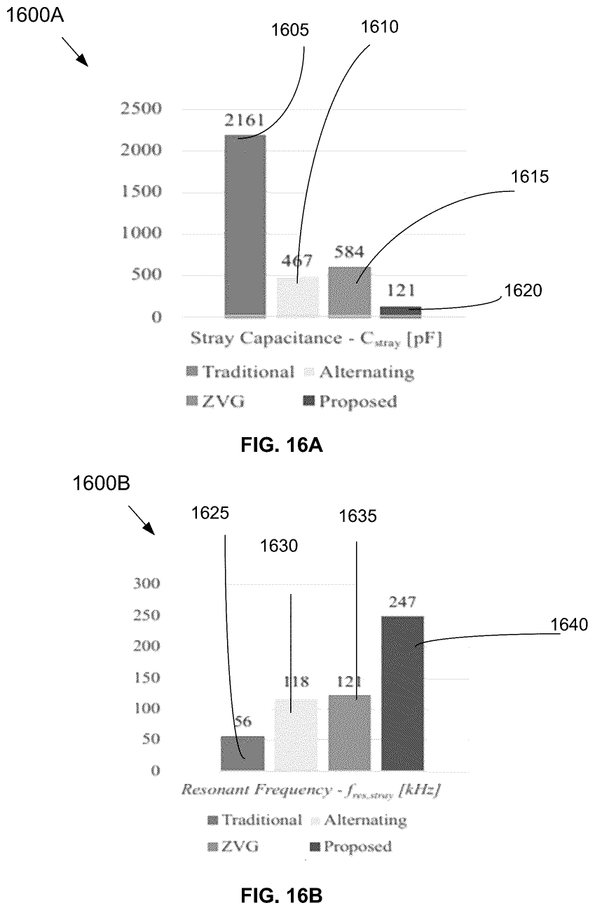

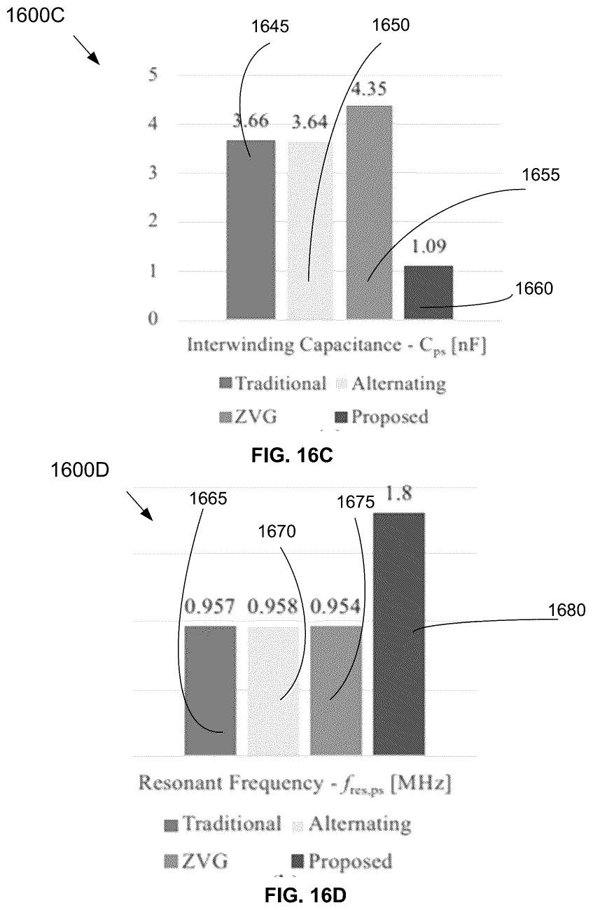

Reference is next made to FIGS. 16A-16B, which illustrate the actual measured stray capacitance values (1600A of FIG. 16A) for the various planar transformers shown in FIG. 14, independent of inductance differences, and the corresponding resonant frequencies (1600B of FIG. 16B). Plot 1605 shows the stray capacitance measurement of a traditional planar transformer, such as transformer 1405. Plot 1610 shows the stray capacitance measurement of an alternating configuration planar transformer, such as transformer 1410. Plot 1615 shows the stray capacitance measurement of a zero-voltage gradient configuration transformer, such as transformer 1415. Plot 1620 shows the stray capacitance measurement of a co-planar configuration transformer, such as transformer 1420.

Plot 1625 shows the corresponding resonant frequency of a traditional planar transformer, such as transformer 1405. Plot 1610 shows the corresponding resonant frequency of an alternating configuration planar transformer, such as transformer 1410. Plot 1615 shows the corresponding resonant frequency of a zero-voltage gradient configuration transformer, such as transformer 1415. Plot 1620 shows the corresponding resonant frequency of a co-planar configuration transformer, such as transformer 1420. As shown, the co-planar configuration transformer has the lowest stray capacitance and approximately 18 times lower capacitance than the traditional transformer.

Reference is next made to FIGS. 16C-16D, which illustrate the actual measured inter-winding capacitance values between the shorted primary and second winding (1600C of FIG. 16C) for the various planar transformers shown in FIG. 14, and the corresponding resonant frequencies (1600D of FIG. 16D). In this test, the primary and secondary winding terminals are shorted separately, and the impedance is measured between the two terminals.

Plot 1645 shows the inter-winding capacitance measurement of a traditional planar transformer, such as transformer 1405. Plot 1650 shows the inter-winding capacitance measurement of an alternating configuration planar transformer, such as transformer 1410. Plot 1655 shows the inter-winding capacitance measurement of a zero-voltage gradient configuration transformer, such as transformer 1415. Plot 1660 shows the inter-winding capacitance measurement of a co-planar configuration transformer, such as transformer 1420.

Plot 1665 shows the corresponding resonant frequency of a traditional planar transformer, such as transformer 1405. Plot 1670 shows the corresponding resonant frequency of an alternating configuration planar transformer, such as transformer 1410. Plot 1675 shows the corresponding resonant frequency of a zero-voltage gradient configuration transformer, such as transformer 1415. Plot 1680 shows the corresponding resonant frequency of a co-planar configuration transformer, such as transformer 1420. As shown, the co-planar configuration transformer has the lowest inter-winding capacitance and a reduction factor reaching four times.

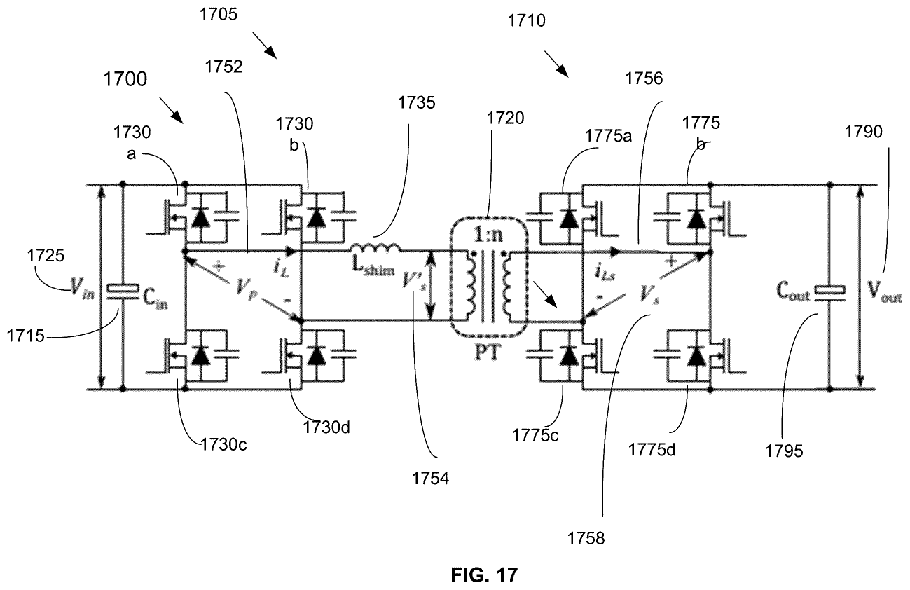

Reference is next made to FIG. 17, which shows a schematic view 1700 of a dual-active bridge (DAB) converter used to power test the various planar transformers shown in FIG. 14. The DAB converter 1700 comprises a primary sub-circuit 1705 and a secondary sub-circuit 1710. Primary sub-circuit 1705 and secondary sub-circuit 1710 are coupled with each other using a transformer Tᵣ (1720) to provide isolation between the primary 1705 and secondary 1710 sub-circuits.

Primary sub-circuit 1705 includes an input voltage, Vᵢₙ, 1725, an input capacitor 1715, full-bridge switches, S₁, S₂, S₃, S₄, 1730a-1730d and shim inductor, Lₛₕᵢₘ, 1735.

Secondary sub-circuit 1710 includes full-bridge switches, S₁, S₂, S₃, S₄, 1775a-1775d, connected in parallel to an output capacitor 1795. Output voltage, Vₒᵤₜ, 1790 is measured across the output capacitor.

The current passing through the shim inductor is depicted as i_{L}, 1752. The secondary side current is depicted as i_{Ls}, 1756. The voltage across the primary windings of the transformer 1720 is depicted as Vₛ′, 1754. The voltage across the secondary windings of the transformer 1720 is depicted as Vₛ, 1758.

To ensure consistency and a fair comparison, the same testing setup and conditions were used for all different types of planar transformers. The transformer 1720 was interchangeable to accommodate the planar transformers shown in FIG. 14. For power testing, a 5-KW DAB converter was set up.

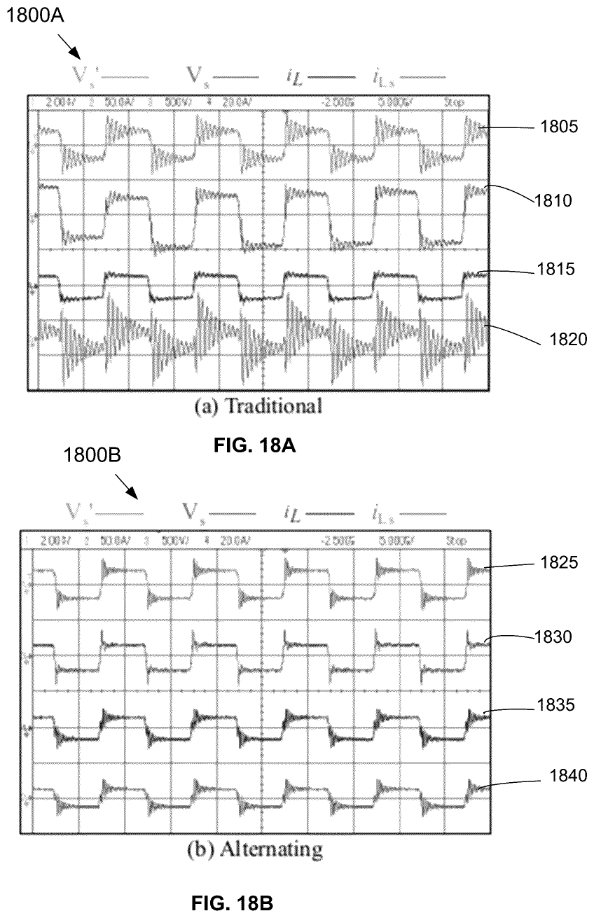

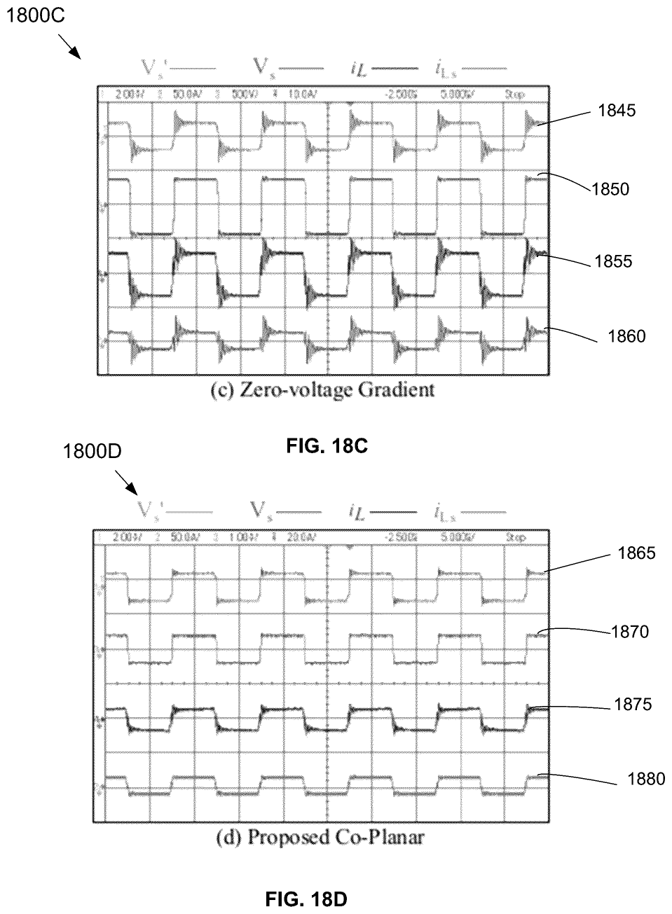

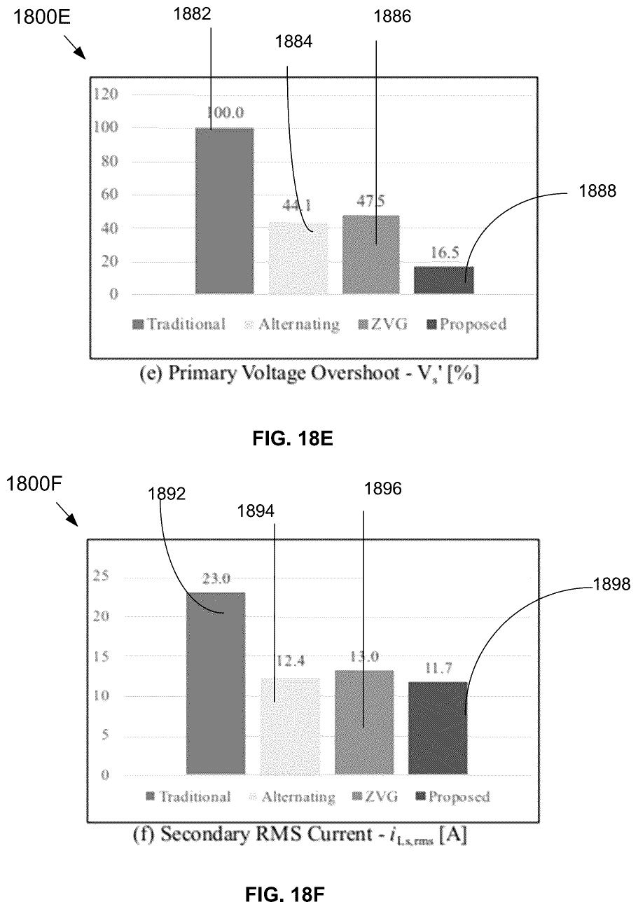

Reference is next made to FIGS. 18A-18D, which illustrate the voltage and current waveforms for all four planar transformer configurations when tested with the DAB converter of FIG. 17. FIG. 18A illustrates a graphical representation 1800A of voltage and current waveforms for the traditional transformer configuration. FIG. 18B illustrates a graphical representation 1800B of voltage and current waveforms for the alternating transformer configuration. FIG. 18C illustrates a graphical representation 1800A of voltage and current waveforms for the ZVG transformer configuration. FIG. 18B illustrates a graphical representation 1800B of voltage and current waveforms for the co-planar transformer configuration. The voltage and current waveforms of FIGS. 18A-18D are measured at an output voltage of 400V and an output power of 4.6 KW in the DAB converter of FIG. 17.

As shown in FIG. 18A, plot 1805 shows the primary winding voltage measured across the primary winding as shown in FIG. 17 (1754) and plot 1810 shows the secondary winding voltage measured across the secondary winding as shown in FIG. 17 (1758). Plot 1815 shows the primary side current as shown in FIG. 17 (1752) and plot 1820 shows the secondary side current as shown in FIG. 17 (1756).

Similarly, as shown in FIG. 18B, plot 1825 shows the primary winding voltage measured across the primary winding as shown in FIG. 17 (1754) and plot 1830 shows the secondary winding voltage measured across the secondary winding as shown in FIG. 17 (1758). Plot 1835 shows the primary side current as shown in FIG. 17 (1752) and plot 1840 shows the secondary side current as shown in FIG. 17 (1756).

Next, as shown in FIG. 18C, plot 1845 shows the primary winding voltage measured across the primary winding as shown in FIG. 17 (1754) and plot 1850 shows the secondary winding voltage measured across the secondary winding as shown in FIG. 17 (1758). Plot 1855 shows the primary side current as shown in FIG. 17 (1752) and plot 1860 shows the secondary side current as shown in FIG. 17 (1756).

For FIG. 18D, plot 1865 shows the primary winding voltage measured across the primary winding as shown in FIG. 17 (1754) and plot 1870 shows the secondary winding voltage measured across the secondary winding as shown in FIG. 17 (1758). Plot 1875 shows the primary side current as shown in FIG. 17 (1752) and plot 1880 shows the secondary side current as shown in FIG. 17 (1756).

As seen, the primary 1865 and the secondary 1870 winding voltages of FIG. 18D demonstrate a substantial reduction in voltage ringing compared to corresponding waveforms of FIGS. 18A-18C. Further, there is a suppression of the high-frequency current oscillations especially at the secondary side current (i_{Ls}) due to the absence of shim inductance on the secondary side.

Reference is next made to FIG. 18E, which illustrates voltage overshoot measurement across the primary winding Vₛ′ of the various transformer configurations of FIG. 14. Plot 1882 shows the primary voltage overshoot measurement of a traditional transformer configuration. Plot 1884 shows the primary voltage overshoot measurement of an alternating transformer configuration. Plot 1886 shows the primary voltage overshoot measurement of a ZVG transformer configuration. Plot 1888 shows the primary voltage overshoot measurement of the co-planar transformer configuration disclosed herein. As seen, plot 1888, corresponding to the co-planar transformer configuration, shows significant improvement in voltage overshoot compared to the other plots corresponding to other transformer configurations.

FIG. 18F illustrates the secondary winding root-mean square (rms) current (i_{Ls,rms}) of the various transformer configurations of FIG. 14. Plot 1892 shows the secondary rms current measurement of a traditional transformer configuration. Plot 1894 shows the secondary rms current measurement of an alternating transformer configuration. Plot 1896 shows the secondary rms current measurement of a ZVG transformer configuration. Plot 1898 shows the secondary rms current measurement of the co-planar transformer configuration disclosed herein. As seen, plot 1898, corresponding to the co-planar transformer configuration, shows significant improvement in rms current compared to the other plots corresponding to other transformer configurations.

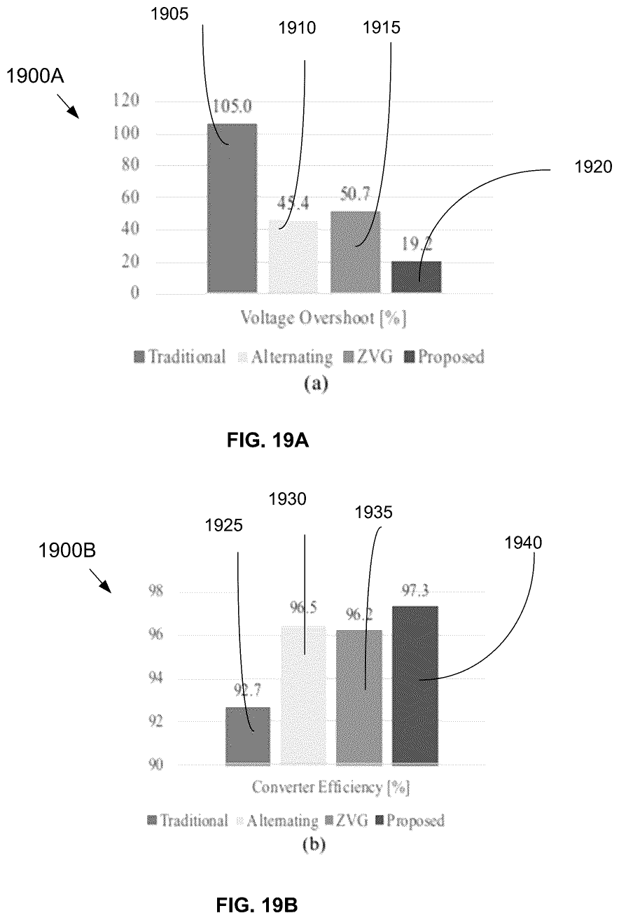

Reference is next made to FIGS. 19A-19B, which illustrate voltage overshoot and converter efficiency recorded at the rated 5 KW power for the various planar configurations of FIG. 14. FIG. 19A illustrates the voltage overshoot measurements of the four planar configurations. Plot 1905 shows the primary voltage overshoot measurement of a traditional transformer configuration. Plot 1910 shows the primary voltage overshoot measurement of an alternating transformer configuration. Plot 1915 shows the primary voltage overshoot measurement of a ZVG transformer configuration. Plot 1920 shows the primary voltage overshoot measurement of the co-planar transformer configuration disclosed herein. As seen, plot 1920 shows substantial reduction in voltage overshoot, by about 81.7% compared to plot 1905, and the total power loss reduction by about 64%.

FIG. 19B illustrates the converter efficiency measurements of the four planar configurations. Plot 1925 shows the converter efficiency measurement of a traditional transformer configuration. Plot 1930 shows the converter efficiency measurement of an alternating transformer configuration. Plot 1935 shows the converter efficiency measurement of a ZVG transformer configuration. Plot 1940 shows the converter efficiency measurement of the co-planar transformer configuration disclosed herein. As seen, plot 1940 shows substantial reduction in voltage overshoot, by about 81.7% compared to plot 1925. As seen, the efficiency of the co-planar transformer, shown by plot 1940, is the highest compared to the other planar transformer configurations.

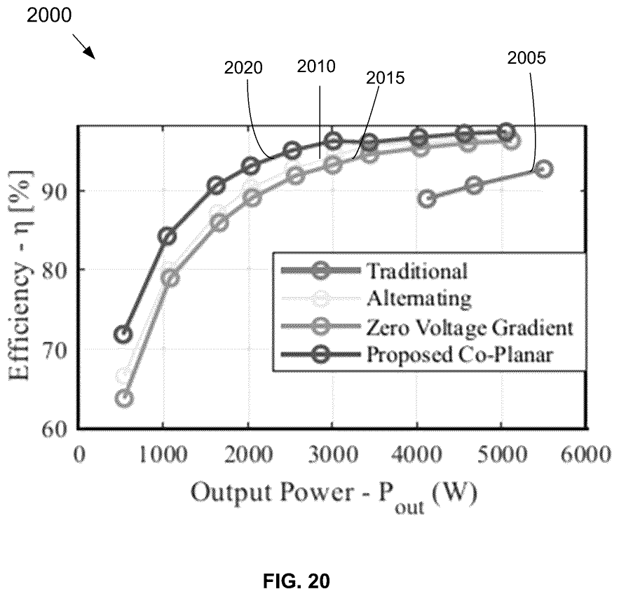

FIG. 20 illustrates a graphical representation 2000 of converter efficiency as a function of output power for various planar transformers of FIG. 14. The efficiency is determined based on input voltage, Vᵢₙ, of 800V and output voltage, Vₒᵤₜ, of 400V. To analyze the performance of the various planar transformers at different operating points, the output power was varied from 10% of the rated power to full power in 10% increments. Plot 2005 shows the converter efficiency for a traditional transformer configuration. Plot 2010 shows the converter efficiency of an alternating transformer configuration. Plot 2015 shows the converter efficiency of a ZVG transformer configuration. Plot 2020 shows the converter efficiency of a co-planar transformer configuration. As seen, plot 2020 has a higher efficiency over the full operating range compared to other planar transformers reaching a peak efficiency of about 97.3%. As well, as seen in plot 2020, the co-planar transformer maintained a higher efficiency at low and higher power levels.

Table Ill highlights the benefits of the co-planar transformers compared to other planar transformers.

TABLE III
Planar Transformers Experimental Results Summary

| Transformer Parameters | Traditional | | Alternating | | ZVG | | Co-Planar | |
|---|---|---|---|---|---|---|---|---|
| Stray Capacitance (C_{stray}) | 2161 | pF | 467 | pF | 584 | pF | 121 | pF |
| Inter-winding Capacitance (Cₚₛ) | 3.7 | nF | 3.6 | nF | 4.4 | nF | 1.1 | nF |

| | | | | |
|---|---|---|---|---|
| Power Converter Efficiency | 92.7% | 96.5% | 96.2% | 97.3% |
| Ringing Voltage Overshoot | 105% | 45.4% | 50.7% | 19.2% |
| Specific Power (kW/kg) | 13.1 | 12.8 | 12.5 | 12.5 |
| Power Density (kW/L) | 28 | 24.6 | 28 | 25.2 |
| Different Board Designs | 2 | 2 | 2 | 1 |

As seen in Table III, the co-planar transformer outperforms in every category, with a small compromise on power density and specific power. This compromise can be easily negated if the thermal management system (TMS) size is accounted for, so a smaller TMS size can be used and potentially reaching higher overall power density and specific power. Depending on the manufacturing technology and budget, a higher quality design can be implemented to increase the window utilization of the co-planar transformer.

The foregoing embodiments and advantages are merely examples and are not to be construed as limiting the present invention. Also, the description of the embodiments of the present invention is intended to be illustrative, and not to limit the scope of the claims, and many alternatives, modifications, and variations will be apparent to those skilled in the art.

We claim:

1. A co-planar transformer comprising:
a printed circuit board comprising a plurality of primary windings and a plurality of secondary windings,
wherein a number of the plurality of primary windings is equal to a number of the plurality of secondary windings;
wherein the plurality of primary windings and the plurality of secondary windings are provided on the printed circuit board; and
wherein the plurality of primary windings and the plurality of secondary windings are in an interleaving configuration, wherein the interleaving is provided horizontally across the printed circuit board.

2. The co-planar transformer of claim 1, wherein:
the printed circuit board is a two-layer board;
the interleaving configuration of the plurality of the primary windings and the plurality of the secondary windings is duplicated on the two layers of the printed circuit board; and
each of the plurality of primary and secondary windings on a top layer of the two-layer board is connected in parallel to a corresponding winding on a bottom layer of the two-layer board through a corresponding via.

3. The co-planar transformer of claim 1, further comprising:
two printed circuit boards; and
wherein the plurality of primary windings of each of a first and a second printed circuit board of the two printed circuit boards are connected in series.

4. The co-planar transformer of claim 3:
wherein the plurality of secondary windings of each of the first and the second printed circuit boards are connected in parallel.

5. The co-planar transformer of claim 3, wherein:
the plurality of primary windings of each of the first and second printed circuit boards are connected through soldered copper rods.

6. The co-planar transformer of claim 4, wherein:
the plurality of secondary windings of each of the first and second printed circuit boards are connected through connection rods inserted through parallel pads for each secondary winding on each board.

7. The co-planar transformer of claim 1, further comprising:
three stacks of printed circuit boards, wherein each stack comprises six printed circuit boards connected in parallel to each other; and
the three stacks are connected in series to each other.

8. A dual-active bridge converter comprising:
a primary circuit coupled to an input voltage,
a secondary circuit coupled to an output voltage;
a co-planar transformer isolating the primary circuit from the secondary circuit;
the co-planar transformer comprising:
a printed circuit board comprising a plurality of primary windings and a plurality of secondary windings;
wherein a number of the plurality of primary windings is equal to a number of the plurality of secondary windings;
wherein the plurality of primary windings and the plurality of secondary windings are provided on the printed circuit board; and
wherein the plurality of primary windings and the plurality of secondary windings are in an interleaving configuration, wherein the interleaving is provided horizontally across the printed circuit board.

9. The dual-active bridge converter of claim 8, wherein the primary circuit comprises four input bridge switches, and the plurality of primary windings comprising a corresponding primary voltage and a primary current.

10. The dual-active bridge converter of claim 9, further comprising an input capacitor in parallel to the four input bridge switches.

11. The dual-active bridge converter of claim 9, wherein the secondary circuit further comprises four output bridge circuits, and the plurality of secondary windings comprising a corresponding secondary voltage and a secondary current.

12. The dual-active bridge converter of claim 11, further comprising an output capacitor in parallel to the four output bridge switches.
